(19) United States
(12) Patent Application Publication
(10) Pub. No.: US 2014/0104543 A1
(43) Pub. Date: Apr. 17, 2014

(54) METHOD FOR INTEGRATING CAMERA ON LIQUID CRSYTAL PANEL, LIQUID CRYSTAL PANEL AND LIQUID-CRYSTAL DISPLAY DEVICE

(71) Applicant: BOE Technology Group Co., Ltd., Beijing (CN)

(72) Inventors: Wenbo Li, Beijing (CN); Yanbing Wu, Beijing (CN); Mi Zhang, Beijing (CN)

(73) Assignee: BOE Technology Group Co., Ltd., Beijing (CN)

(21) Appl. No.: 14/050,736

(22) Filed: Oct. 10, 2013

(30) Foreign Application Priority Data
Oct. 11, 2012 (CN) 201210384120.7

(51) Int. Cl. G02F 1/13; H05K 3/30

(52) U.S. Cl. CPC G02F 1/1313; H05K 3/30
USPC 349/84; 29/832

(57) ABSTRACT

A method for integrating a camera on a liquid crystal panel is provided, the liquid crystal panel comprises a counter substrate, an array substrate and the integrated camera, the camera includes an integrated chip and a liquid crystal lens; the integrated chip of the camera is arranged on the array substrate; and liquid crystal molecules are filled between the counter substrate and the array substrate to form the liquid crystal lens of the camera. The liquid crystal panel can realize integrating of the camera on the liquid crystal panel with a narrow frame or without a frame.

### TECHNICAL FIELD

Embodiments of the present disclosure relates to a method for integrating a camera on a liquid crystal panel, the liquid crystal panel and a liquid-crystal display device.

### BACKGROUND

Camera, also known as PC camera, PC eye, etc., is employed as a video input device and widely applied in the aspects of video conference, tele-medicine, real-time monitor or the like. In recent years, with the development of the internet technology, the continuous improvement of the internet speed and the mature of the technology of photosensitive imaging devices, communicating parties can chat and communicate with each other smoothly via video and voice on the internet through the cameras. Cameras play an increasingly important role in people's lives and work.

FIG. 1 is a schematic structural view of a traditional camera. The camera comprises a lens 10, an optical filter 11, an image sensor 12, a digital signal processor (DSP) 13, a compression and encoding processor 14, and a power supply (not shown). The lens 10 may be an optical glass lens; external light is introduced from the lens 10 and subjected to color filtering through the optical filter 1. The image sensor 12 may be a charge coupled device (CCD) or a complementary metal oxide semiconductor (CMOS) device and is configured to convert optical signals, subjected to color filtering by the optical filter, into electrical signals. The DSP 13 is configured to optimize digital image signals. Two types of operating voltages, i.e., 3.3V and 2.5V, are required by the camera, and in addition, a good internal electric source of the camera can ensure the stable operation of the camera. An optical image of a scene formed from the lens 10 is projected on the surface of the image sensor 12 and converted into an electrical signals; the electrical signals are converted into digital image signals after subjected to analog-to-digital (A/D) conversion; and the digital image signals are hence sent into the DSP 13 for further processing, compressed by the compression and encoding processor 14, finally outputted into, for instance, a computer for storing or processing through an interface circuit, and presented to users through a display. Of course, the camera may further comprise a central processing unit (CPU) 16, a random access memory (RAM) 17, an FLASH memory (FLASH) 15, an interface 18 and other commonly used components.

At current camera technology has been widely applied in the fields of mobile phones, notebooks, and domestic and commercial televisions. A front camera is usually integrated on a frame around a liquid crystal panel. However, with the popularity of display screens with narrow frames or even without frames, the area of a display panel, adapted to arrange a camera, is reduced, or even there is no area for arranging the camera. Therefore, how to integrate a camera on a liquid crystal panel with a narrow frame or even without a frame has become one of the technical problems to be solved.

### SUMMARY

Embodiments of the present disclosure provide a method for integrating a camera on a liquid crystal panel, a liquid crystal panel and a liquid-crystal display device, capable of realizing integrating of the camera on the liquid crystal panel with a narrow frame or without a frame.

In one aspect, the present disclosure provides a method for integrating a camera on a liquid crystal panel, wherein the liquid crystal panel comprises an array substrate and a counter substrate. The method comprises: arranging an integrated chip of the camera on the array substrate or directly forming circuits for achieving the function of the integrated chip on the array substrate; and filling liquid crystal molecules between the counter substrate and the array substrate to form a liquid crystal lens of the camera.

In another aspect, the present disclosure provides a liquid crystal panel, comprising a counter substrate, an array substrate and an integrated camera, wherein the camera includes an integrated chip and a liquid crystal lens; the integrated chip of the camera is arranged on the array substrate; and liquid crystal molecules are filled between the counter substrate and the array substrate to form the liquid crystal lens of the camera.

In still another aspect, the present disclosure provides a liquid-crystal display device, which comprises a liquid crystal panel, wherein the liquid crystal panel includes the foregoing liquid crystal panel.

Further scope of applicability of the present disclosure will become apparent from the detailed description given hereinafter. However, it should be understood that the detailed description and specific examples, while indicating preferred embodiments of the disclosure, are given by way of illustration only, since various changes and modifications within the spirit and scope of the disclosure will become apparent to those skilled in the art from the following detailed description.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a schematic structural view of a traditional camera;

FIG. 2 is a schematic diagram of a method for integrating a camera on a liquid crystal panel, provided by an embodiment of the present disclosure;

FIG. 3 is a schematic structural view of a camera, in which circuits configured to achieve the functions of a compression algorithm processor and a CPU respectively are integrated on a same chip, provided by an embodiment of the present disclosure;

FIG. 4 is a schematic structural view of a camera, in which circuits configured to achieve the functions of a compression algorithm processor, a CPU, an FLASH and a RAM respectively are integrated on a same chip, provided by an embodiment of the present disclosure;

FIG. 5 is a schematic structural view of a camera, in which circuits configured to achieve the functions of a compression algorithm processor, a CPU, an FLASH, a RAM and a DSP respectively are integrated on a same chip, provided by an embodiment of the present disclosure;

FIG. 6 is a schematic structural view of a camera, in which circuits configured to achieve the functions of a compression algorithm processor, a CPU, an FLASH, a RAM, a DSP and an image sensor respectively are integrated on a same chip, provided by an embodiment of the present disclosure;

FIG. 7 is a schematic diagram illustrating the imaging principle of a liquid crystal lens in an embodiment of the present disclosure;

FIG. 8 is a schematic diagram illustrating the refractive index distribution of the liquid crystal lens in an embodiment of the present disclosure;

FIG. 9 is a schematic diagram illustrating the definition of the polar angle of liquid crystal molecules in an embodiment of the present disclosure;

FIG. 10 is a schematic structural view of a liquid crystal panel provided by an embodiment of the present disclosure;

FIGS. 11a to 11d are schematic diagrams of four examples of the position of divided partial spaces in an embodiment of the present disclosure; and

FIG. 12 is a schematic structural view of a liquid crystal panel provided by an embodiment of the present disclosure.

### DETAILED DESCRIPTION

In order to integrate a camera on a liquid crystal panel with a narrow frame or even without a frame, embodiments of the present disclosure provide a method for integrating a camera on a liquid crystal panel, a liquid crystal panel and a liquid-crystal display device.

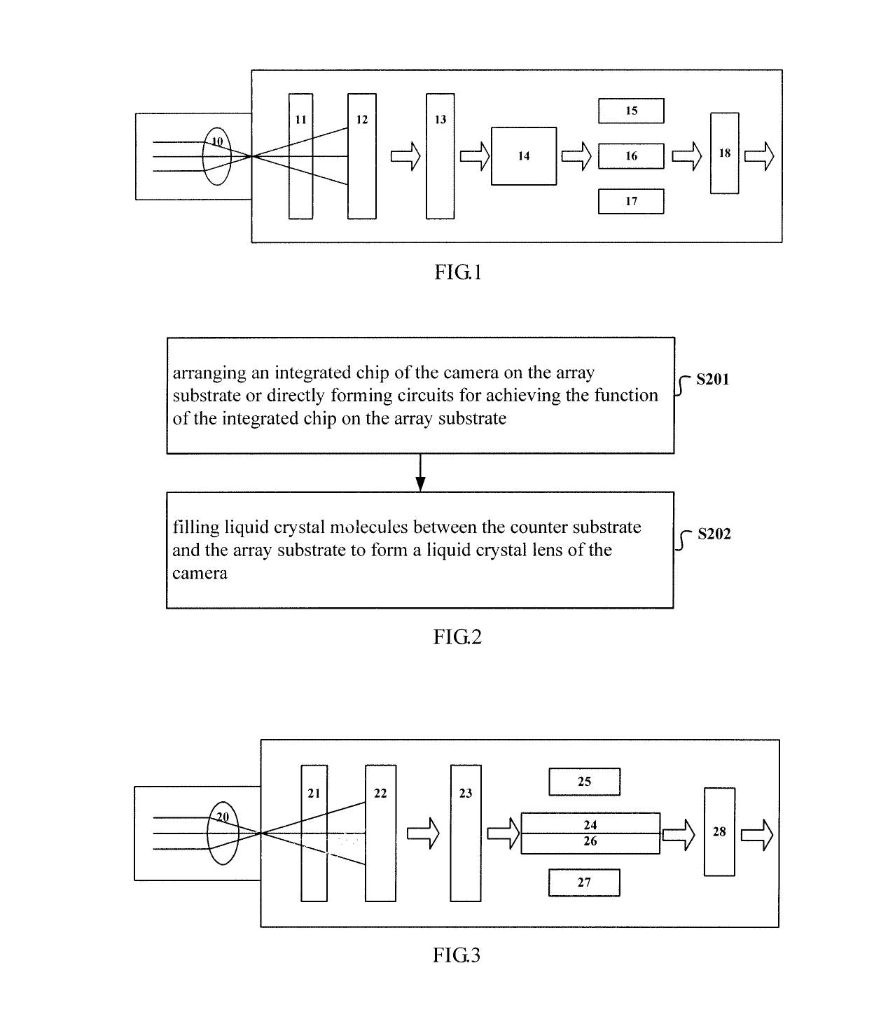

FIG. 2 is a schematic diagram of the method for integrating a camera on a liquid crystal panel, provided by an embodiment of the present disclosure. The liquid crystal panel comprises an array substrate and a counter substrate, and a liquid crystal layer is disposed between the array substrate and the counter substrate; the counter substrate is, for instance, a color filter substrate. The method for integrating the camera on the liquid crystal panel may comprise the following processes.

S201: arranging an integrated chip on the array substrate or directly forming circuits for achieving the function of the integrated chip on the array substrate.

The integrated chip may include an image sensor, a signal processing and acontrol device, and a memory device, and the image sensor may be a CCD or a CMOS.

For instance, the circuits configured to achieve the functions of any combination of a CPU, a RAM, an FLASH, a DSP, a compression and encoding processor, and the image sensor or to achieve the functions of all the devices are integrated into the integrated chip. A RAM and an FLASH are used for data storage and are examples of the memory device in the camera of an embodiment of the present disclosure. The present disclosure is not limited to the specific examples. In addition, a CPU, a DSP, and a compression and encoding processor are configured to process image signals acquired by the image sensor, and are examples of the signal processing and control device in the camera of an embodiment of the present disclosure. The present disclosure is not limited to the specific examples.

As for the foregoing examples, for instance, the circuits configured to achieve the functions of a CPU, a RAM, an FLASH, a DSP, a compression and encoding processor, and an image sensor respectively may be integrated on the integrated chip according to the following processes:

Firstly, forming the circuits configured to achieve the functions of a CPU, a RAM, an FLASH, a DSP, and a compression and encoding processor respectively on a same chip; and

secondly, integrating circuits for achieving the function of an image sensor on the chip, on which the circuits configured to achieve the functions of the CPU, the RAM, the FLASH, the DSP and the compression and encoding processor respectively are formed, by photolithography technology, so as to form the integrated chip.

As another example, firstly, the circuits configured to achieve the functions of the compression algorithm processor and the CPU may be respectively formed on the same chip. FIG. 3 is a schematic structural view of the example of an integrated camera. The example of the camera includes a lens 20, an optical filter 21, an image sensor 22, a DSP 23, a compression and encoding processor 24, an FLASH 25, a CPU 26, an RAM 27, an interface 28 and other components, and the interface 28 is configured to connect the camera and an input circuit of another system (such as a computer or a display for employing captured images); and the lens 20 herein is a liquid crystal lens.

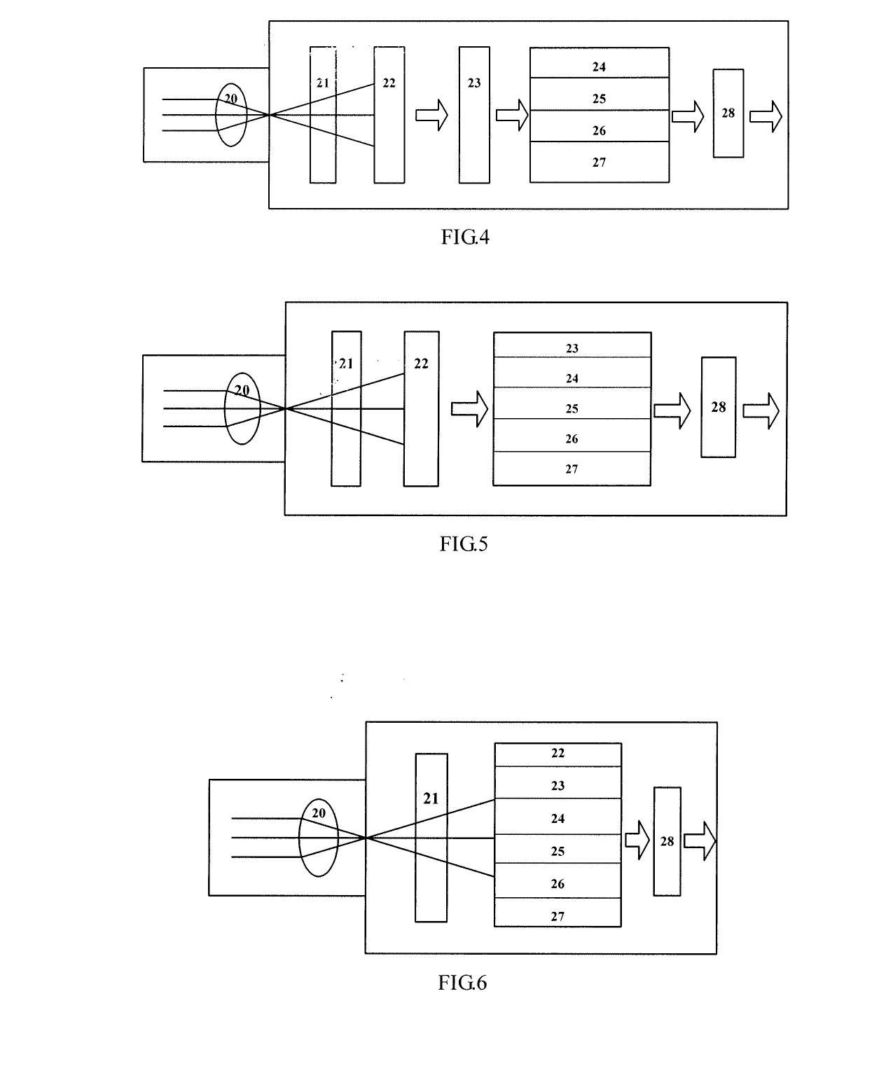

Further, for instance, the circuits configured to achieve the functions of the FLASH and the RAM are respectively formed on the chip. FIG. 4 is a schematic structural view of the example of the integrated camera.

Furthermore, for instance, the circuit for achieving the function of the DSP is formed on the chip. FIG. 5 is a schematic structural view of the example of the integrated camera.

Finally, for instance, the circuit for achieving the function of the image sensor is formed on the chip by compatible photolithography technology to obtain the integrated chip. FIG. 6 is a schematic structural view of an example of the integrated camera.

It should be noted that the sequence of the circuits, configured to achieve the functions of various modules, formed on the same chip respectively is not limited in the embodiment of the present disclosure. The forming sequence of the circuits can be determined based on actual conditions.

After the integrated chip is obtained, the integrated chip may be arranged on the array substrate by bonding for example.

Moreover, circuits for achieving the function of the integrated chip may be directly formed on the array substrate. In this way, the circuits configured to achieve the functions of various modules are not required for integration. For instance, as for the foregoing examples, the circuits configured to achieve the functions of the CPU, the RAM, the FLASH, the DSP, the compression and encoding processor and the image sensor can be respectively formed on the array substrate. It should be noted that direct forming of the circuits for achieving the function of the integrated chip on the array substrate may be completed synchronously with the manufacturing of the array substrate of the liquid crystal panel, by the photolithography processes including exposure and development.

The array substrate may be, but not limited to, a monocrystalline silicon array substrate, a low-temperature polysilicon array substrate, a high-temperature polysilicon array substrate, or any other array substrate in which the peripheral integrated circuits have high mobility.

S202: filling liquid crystal molecules between the counter substrate and the array substrate to form a liquid crystal lens.

For instance, liquid crystals may be filled between a color filter substrate and an array substrate through TFT-LCD technologies, so as to form a “planar” liquid crystal lens. The color filter substrate is an example of the counter substrate. The liquid crystal lens focuses or diverges light beams by utilization of the birefringent characteristic of the liquid crystal molecules and the characteristic of arrangement according to distribution of electric fields of the liquid crystal molecules, so as to achieve the functions of a traditional lens (e.g., a plastic or glass lens). The size of the liquid crystal lens can be set as required. The liquid crystal lens cooperates with the integrated chip disposed on the array substrate to form a camera. Hence, the camera in the embodiment of the present disclosure is integrated into the corresponding liquid crystal panel.

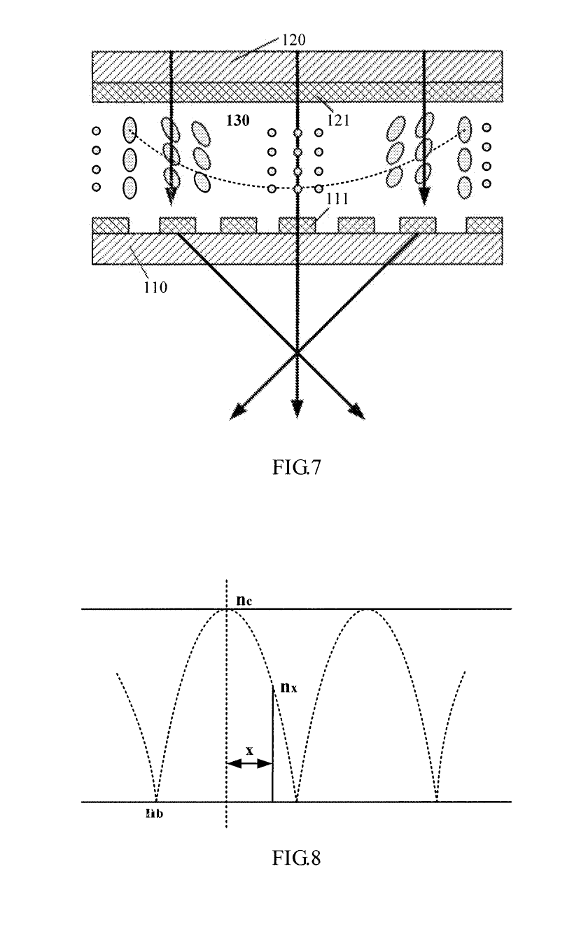

FIG. 7 is a schematic diagram illustrating the imaging principle of the liquid crystal lens. As illustrated in FIG. 7, the liquid crystal lens of the embodiment of the present disclosure comprises an array substrate 110, a counter substrate 120 and a liquid crystal layer 130 disposed between the array substrate 110 and the counter substrate 120. Pixel drive circuits, for instance, passive matrix drive circuits or active matrix drive circuits, more specifically, active matrix drive circuits employing thin film transistors (TFT) as switching elements, are arranged on the array substrate 110. Moreover, in order to form a liquid crystal lens, an electrode 111 is arranged on the array substrate 110; an electrode 121 is arranged on the counter substrate 120; when the operating voltage is applied across the electrode 111 and the electrode 121, an electric filed is formed between the electrode 111 and the electrode 121 and configured to deflect the liquid crystal molecules in the liquid crystal layer 130; and drive circuits for the electrode 111 and the electrode 121 are, for instance, achieved through TFT drive circuits in a general liquid crystal panel. The present disclosure is not limited to specific structures of the circuits as illustrated in FIG. 7.

Compared with a traditional lens, the liquid crystal lens also has the following advantages that: the traditional lens can magnify a portion of photo through digital technology only to achieve the visual effect of “zooming” and cannot achieve real optical zoom, but the liquid crystal lens can change the arrangement direction of the liquid crystal molecules by the change of the applied operating voltage and hence achieve the effect of adjusting the physical focus. The light and thin characteristic of the liquid crystal lens is another great advantage, and the efficient optical zoom effect can be achieved in a small space; and all the traditional lenses are perceptible lenses and hence the position of a camera in the equipment is notable as well, which is unfavorable for the monitoring and protection of confidential information, but the “planar” liquid crystal lens formed by utilization of the characteristics of the liquid crystal molecules almost does not have any difference from the liquid crystal panel observed from the surface and thus has strong concealment.

FIG. 8 is a schematic diagram illustrating the distribution of the refractive index of the liquid crystal lens, where

$$Δ n \cdot D = \frac{{x}^{2}}{2 f}$$

and Δn=n_{c}=nₓ. The definitions of various parameters are as follows: Δn refers to the birefringence of liquid crystal molecules; D refers to the thickness of the liquid crystal lens; x refers to the distance with respect to the center of the lens; f refers to the focus of the lens; n_{c} refers to the refractive index of the center of the liquid crystal lens; nₓ refers to the refractive index of a position at distance x from the center of the liquid crystal lens; n_{b} refers to the refractive index of both ends of the liquid crystal lens; and the birefringence of the liquid crystal molecules is Δn=n_{e eff}−nₒ. As for the liquid crystal molecules of the liquid crystal layer in the structure, for instance, as illustrated in FIG. 7, the effective refractive index of extraordinary light of the liquid crystal molecules satisfies the following formula:

$${n}_{e eff} = \frac{{n}_{o} {n}_{e}}{\sqrt{{n}_{o}^{2} {cos}^{2} θ + {n}_{e}^{2} {sin}^{2} θ}} ,$$

where n_{e eff} refers to the effective refractive index of the extraordinary light of the liquid crystal molecules; nₑ refers to the refractive index of the extraordinary light of the liquid crystal molecules; and θ refers to the polar angle of the liquid crystal molecules.

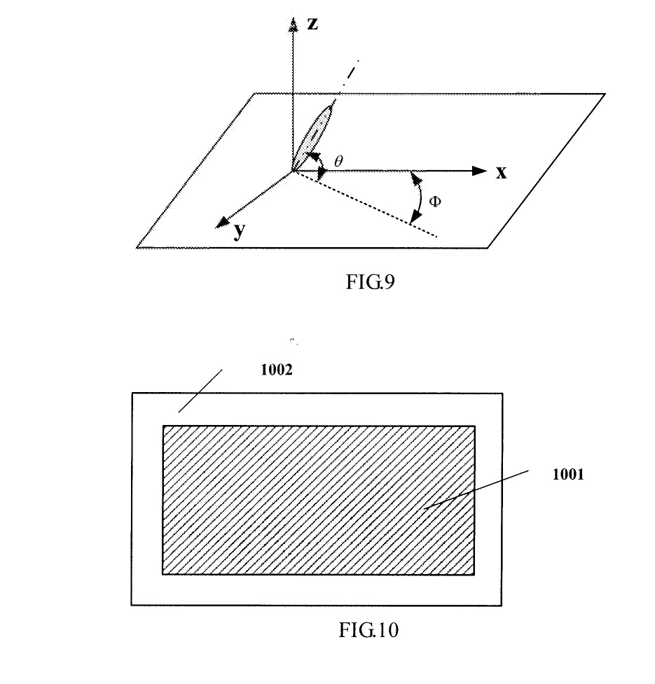

FIG. 9 is a schematic diagram illustrating the definition of the polar angle of the liquid crystal molecules. Moreover, φ refers to the azimuth of the liquid crystal molecules. The phase delay of the liquid crystal molecules is illustrated as follows:

$$Δ nd = ( {n}_{e eff} - {n}_{o} ) d = ( \frac{{n}_{o} {n}_{e}}{\sqrt{{n}_{o}^{2} {cos}^{2} θ + {n}_{e}^{2} {sin}^{2} θ}} - {n}_{o} ) d ,$$

Therefore, the birefringence of the liquid crystal molecules can be changed by the application of different voltages. As seen from the formula

$$Δ n \cdot D = \frac{{x}^{2}}{2 f} ,$$

the focus of the liquid crystal lens can be adjusted through the adjustment on Δn.

For instance, in order to not affect the display effect of the liquid crystal panel, the liquid crystal lens provided by the embodiment of the present disclosure may be disposed at a non-effective display area of the liquid crystal panel. For example, there may be two ways to arrange the liquid crystal lens as follows.

First way: the liquid crystal lens is arranged at a peripheral circuit area of the liquid crystal panel.

FIG. 10 is a schematic diagram of an example of the position relation between the liquid crystal lens and the liquid crystal panel. The liquid crystal lens is disposed in the peripheral circuit area of the liquid crystal panel, and drive circuits of the liquid crystal lens (namely the integrated chip) are integrated on the array substrate. The shadow area as illustrated in FIG. 10 is an effective display area 1001, and the peripheral blank area is a circuit area 1002.

Second way: a partial space is divided from the original effective display area of the liquid crystal panel and configured to arrange the liquid crystal lens.

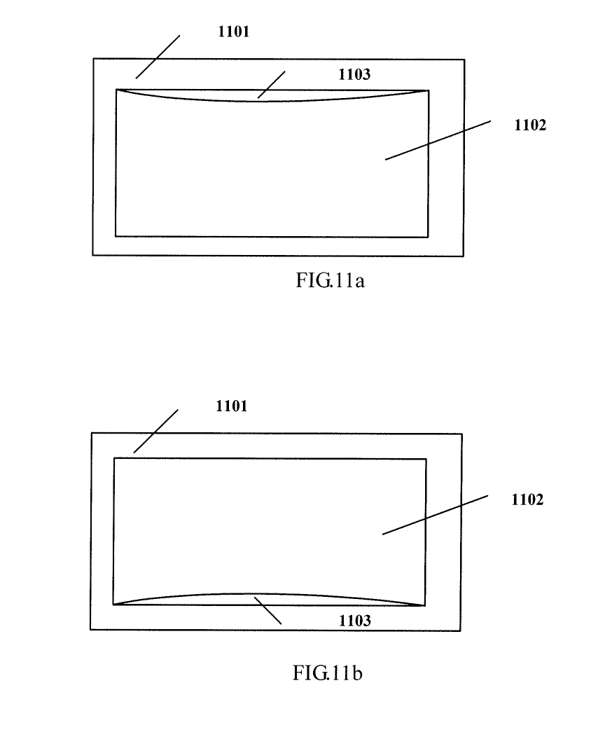

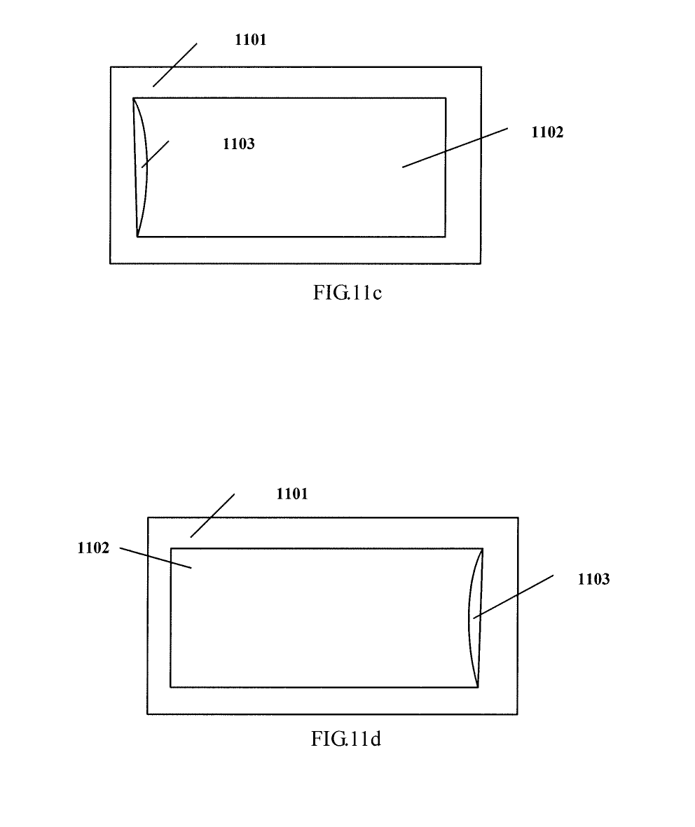

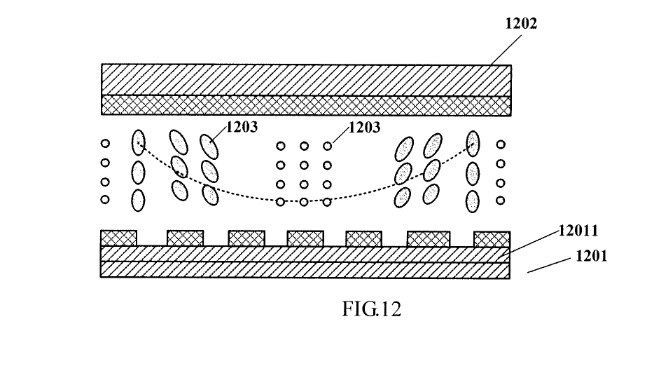

FIGS. 11a to 11d are schematic diagrams of examples of the position of the divided partial space. In the embodiment, the liquid crystal panel comprises a peripheral circuit area 1101, an effective display area 1102, and a liquid crystal lens arrangement area 1103. In the example as illustrated in FIG. 11a, the liquid crystal lens arrangement area 1103 is disposed at the upper side of the effective display area 1102. In the example as illustrated in FIG. 11b, the liquid crystal lens arrangement area 1103 is disposed at the lower side of the effective display area 1102. In the example as illustrated in FIG. 11c, the liquid crystal lens arrangement area 1103 is disposed at the left side of the effective display area 1102. In the example as illustrated in FIG. 11d, the liquid crystal lens arrangement area 1103 is disposed at the right side of the effective display area 1102. It should be noted that: as the divided partial space configured to arrange the liquid crystal lens cannot be used for image display any more, the selection principle is that the position of the liquid crystal lens does not affect the overall display effect of the liquid crystal panel. Therefore, the liquid crystal lens may be arranged on any of the four edges of the original effective display area, so as to reduce the impact on the display effect as much as possible.

In the embodiment of the present disclosure, the camera and relevant drive circuits (the integrated chip) are integrated or attached (e.g., bonded) on the liquid crystal panel by circuit integration process, without occupying the area of an outer frame. Meanwhile, the “planar” liquid crystal lens can achieve physical zooming and have stronger picture capturing capability.

Another embodiments of the present disclosure further provide a liquid crystal panel and a liquid-crystal display device. As the operating principles of the devices are similar to those of the method for integrating the camera on the liquid crystal panel, the description of the devices can refer to the method for integrating the camera on the liquid crystal panel, and the description will not be repeated for simplicity.

FIG. 12 is a schematic structural view of the liquid crystal panel provided by the embodiment of the present disclosure. The liquid crystal panel comprises a counter substrate (e.g. a color filter substrate) 1202 and an array substrate 1201, and an integrated chip 12011 is arranged on the array substrate 1201; and liquid crystal molecules 1203 are filled between the counter substrate 1202 and the array substrate 1201 to form a liquid crystal lens. When a color filter is provided on the array substrate 1201, the color filter may be not formed on the counter substrate 1202 again.

For instance, part or all of the devices from the group consisting of a CPU, an RAM, an FLASH, a DSP, a compression and encoding processor, and an image sensor may be integrated into the integrated chip 12011. An optical filter 21 and the image sensor 22 are arranged at the rear side of the liquid crystal lens 20 to filter imaging light incident from the liquid crystal lens 20 and acquire image signals.

For instance, the array substrate 1201 may be, but not limited to, a monocrystalline silicon array substrate, a low-temperature polysilicon array substrate or a high-temperature polysilicon array substrate and may be any substrate in which the peripheral integrated circuits have higher migration.

For instance, the effective refractive index of extraordinary light of the liquid crystal molecules 1203 filled between the counter substrate 1202 and the array substrate 1201 satisfies the following condition:

$${n}_{e eff} = \frac{{n}_{o} {n}_{e}}{\sqrt{{n}_{o}^{2} {cos}^{2} θ + {n}_{e}^{2} {sin}^{2} θ}} ,$$

where n_{e eff} refers to the effective refractive index of the extraordinary light of the liquid crystal molecules; nₒ refers to the refractive index of ordinary light of the liquid crystal molecules; nₑ refers to the refractive index of the extraordinary light of the liquid crystal molecules; and θ refers to the polar angle of the liquid crystal molecules.

The liquid crystal panel, a backlight (not shown), and an integrated circuit board configured to provide control signals for the liquid crystal panel can be combined to form the liquid-crystal display device. In the foregoing devices, except that the liquid crystal panel adopts the liquid crystal panel provided by the embodiment of the present disclosure, the structures of other parts may be the same as those of the traditional liquid crystal panel and will not be further described herein. The liquid-crystal display device may be applied to monitors, televisions, mobile phones, cameras and the like.

The method for integrating a camera on a liquid crystal panel, the liquid crystal panel and the liquid-crystal display device, provided by the embodiments of the present disclosure, can realize integrating of the camera on the liquid crystal panel without occupying a frame area of the liquid crystal panel, by integrating the circuits configured to achieve the functions of a CPU, a RAM, an FLASH, a DSP, a compression and encoding processor, and an image sensor respectively on the integrated chip, arranging the integrated chip on the array substrate or directly forming the circuit for achieving the function of the integrated chip on the array substrate, and filling the liquid crystals between the color filter substrate and the array substrate to form the liquid crystal lens.

Obviously, various changes and modifications can be made to the present disclosure by those skilled in the art without departing from the spirit and scope of the present disclosure. Therefore, if the changes and the modifications of the present disclosure fall within the scope of the appended claims of the present disclosure and equivalent techniques thereof, the present disclosure is also intended to include the changes and the modifications.

1. A method for integrating a camera on a liquid crystal panel, the liquid crystal panel comprising an array substrate and a counter substrate, the method comprising:
arranging an integrated chip of the camera on the array substrate or directly forming circuits for achieving the function of the integrated chip on the array substrate; and
filling liquid crystal molecules between the counter substrate and the array substrate to form a liquid crystal lens of the camera.

2. The method according to claim 1, wherein an image sensor, a signal processing and control device and a memory device are integrated into the integrated chip;
circuits configured to achieve the functions of the signal processing and control device and the memory device are respectively formed on the same chip; and
circuits for achieving the function of the image sensor are integrated on the chip to form the integrated chip.

3. The method according to claim 1, wherein liquid crystals are filled between the counter substrate and the array substrate with thin-film transistor liquid crystal display (TFT-LCD) technology to form the liquid crystal lens.

4. The method according to claim 2, wherein liquid crystals are filled between the counter substrate and the array substrate with thin-film transistor liquid crystal display (TFT-LCD) technology to form the liquid crystal lens.

5. The method according to claim 1, wherein the array substrate includes a monocrystalline silicon array substrate, a low-temperature polysilicon array substrate or a high-temperature polysilicon array substrate.

6. The method according to claim 2, wherein the array substrate includes a monocrystalline silicon array substrate, a low-temperature polysilicon array substrate or a high-temperature polysilicon array substrate.

7. The method according to claim 1, wherein an effective refractive index of extraordinary light of the liquid crystal molecules satisfies the following formula:
$${n}_{e eff} = \frac{{n}_{o} {n}_{e}}{\sqrt{{n}_{o}^{2} {cos}^{2} θ + {n}_{e}^{2} {sin}^{2} θ}} ,$$
where n_{e eff} refers to the effective refractive index of the extraordinary light of the liquid crystal molecules;
nₒ refers to a refractive index of ordinary light of the liquid crystal molecules;
nₑ refers to a refractive index of the extraordinary light of the liquid crystal molecules; and
θ refers to a polar angle of the liquid crystal molecules.

8. The method according to claim 1, wherein the liquid crystal lens is disposed at a non-effective display area of the liquid crystal panel.

9. The method according to claim 2, wherein the liquid crystal lens is disposed at a non-effective display area of the liquid crystal panel.

10. A liquid crystal panel, comprising a counter substrate, an array substrate and an integrated camera, wherein the camera including an integrated chip and a liquid crystal lens; wherein
the integrated chip of the camera is arranged on the array substrate; and
liquid crystal molecules are filled between the counter substrate and the array substrate to form the liquid crystal lens of the camera.

11. The liquid crystal panel according to claim 10, wherein the array substrate includes a monocrystalline silicon array substrate, a low-temperature polysilicon array substrate or a high-temperature polysilicon array substrate.

12. The liquid crystal panel according to claim 10, wherein an effective refractive index of extraordinary light of the liquid crystal molecules satisfies the following formula:
$${n}_{e eff} = \frac{{n}_{o} {n}_{e}}{\sqrt{{n}_{o}^{2} {cos}^{2} θ + {n}_{e}^{2} {sin}^{2} θ}} ,$$
where n_{e eff} refers to the effective refractive index of the extraordinary light of the liquid crystal molecules;
nₒ refers to a refractive index of ordinary light of the liquid crystal molecules;
nₑ refers to a refractive index of the extraordinary light of the liquid crystal molecules; and
θ refers to a polar angle of the liquid crystal molecules.

13. The liquid crystal panel according to claim 10, wherein an image sensor, a signal processing and control device and a memory device are integrated into the integrated chip.

14. The liquid crystal panel according to claim 11, wherein an image sensor, a signal processing and control device and a memory device are integrated into the integrated chip.

15. A liquid-crystal display device, comprising a liquid crystal panel, wherein the liquid crystal panel includes the liquid crystal panel according to claim 10.
